(19) United States
(12) Patent Application Publication
(10) Pub. No.: US 2026/0136936 A1
(43) Pub. Date: May 14, 2026

(54) BONDING SCHEME FOR REDUCED CROSSTALK-INDUCED JITTER IN A MEMORY DEVICE

(71) Applicant: Micron Technology, Inc., Boise, ID (US)

(72) Inventors: Jitendra Kumar, Mangawan (IN); Srinivas Pindi, Bandlaguda Jagir (IN)

(21) Appl. No.: 19/371,557

(22) Filed: Oct. 28, 2025

Related U.S. Application Data
(60) Provisional application No. 63/718,937, filed on Nov. 11, 2024.

(51) Int. Cl. H01L 23/00; G11C 11/4093; H01L 25/04; H10B 80/00

(52) U.S. Cl. CPC H10W 42/00; G11C 11/4093; H10B 80/00; H10W 90/00; H10W 90/24; H10W 90/752

(57) ABSTRACT

Systems, methods, and apparatuses are provided for a bonding scheme for reduced crosstalk-induced jitter in a memory device and enabling high speed data transfers to and from the memory device with high storage capacity. An apparatus can include an I/O interface and a first number of memory dies, wherein each memory die of the first number of memory dies is coupled to a different memory die of the first number of memory dies in a cascading pattern via one or more conductive lines forming a first portion of a ground path to the I/O interface. Further, the apparatus includes a second number of memory dies coupled to the I/O interface via one or more second conductive lines forming a second portion of the ground path to the I/O interface, wherein the second number of memory dies is stacked on the first number of memory dies in the cascading pattern.

### PRIORITY INFORMATION

This application claims the benefit of U.S. Provisional Application No. 63/718,937, filed on Nov. 11, 2024, the contents of which are incorporated herein by reference.

### TECHNICAL FIELD

Embodiments of the disclosure relate generally to a memory sub-system, and more specifically, relate to bonding scheme for reduced crosstalk-induced jitter in a memory device.

### BACKGROUND

Memory devices are typically provided as internal, semiconductor, integrated circuits and/or external removable devices in computers or other electronic devices. There are many different types of memory including volatile and non-volatile memory. Volatile memory can require power to maintain its data and can include random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), and resistance variable memory such as phase change random access memory (PCRAM), resistive random access memory (RRAM), ferroelectric random access memory (FERAM), magnetic random access memory (MRAM), and programmable conductive memory, among others.

Memory devices can be utilized as volatile and non-volatile memory for a wide range of electronic applications in need of high memory densities, high reliability, and low power consumption. Non-volatile memory may be used in, for example, personal computers, portable memory sticks, solid state drives (SSDs), digital cameras, cellular telephones, portable music players such as MP3 players, and movie players, among other electronic devices.

Memory devices can include memory cells that can store data based on the charge level of a storage element or can store data based on their conductivity state. Such memory cells can be programmed to store data corresponding to a target data state by varying the charge level of the storage element or by varying the conductivity level of the storage element. For example, sources of an electrical field or energy, such as positive or negative electrical pulses (e.g., positive or negative voltage or current pulses), can be applied to the memory cell (e.g., to the storage element of the cell) for a particular duration to program the cell to a target data state.

A memory cell can be programmed to one of several data states. For example, a single level memory cell (SLC) can be programmed to a targeted one of two different data states, which can be represented by the binary units 1 or 0 and can depend on whether the capacitor of the cell is charged or uncharged. As an additional example, some memory cells can be programmed to a targeted one of more than two data states (e.g., 1111, 0111, 0011, 1011, 1001, 0001, 0101, 1101, 1100, 0100, 0000, 1000, 1010, 0010, 0110, and 1110). Such cells may be referred to as multi state memory cells, multi-unit cells, or multilevel cells (MLCs). MLCs can provide higher density memories without increasing the number of memory cells since each cell can represent more than one digit (e.g., more than one data bit).

### BRIEF DESCRIPTION OF THE DRAWINGS

FIG. 1 illustrates an example computing system that includes a memory sub-system in accordance with some embodiments of the present disclosure.

FIG. 2A illustrates bonding scheme for reduced crosstalk-induced jitter in a memory device in accordance with some embodiments of the present disclosure.

FIG. 2B illustrates another embodiment of a bonding scheme for reduced crosstalk-induced jitter in a memory device in accordance with some embodiments of the present disclosure.

FIG. 3 illustrates conductive lines for bonding scheme for reduced crosstalk-induced jitter in a memory device in accordance with some embodiments of the present disclosure.

FIG. 4 is a block diagram of an example computer system in which embodiments of the present disclosure may operate.

### DETAILED DESCRIPTION

The present disclosure includes apparatuses, methods, and systems for a bonding scheme for reduced crosstalk-induced jitter in a memory device. An embodiment includes an apparatus comprising an input/output (I/O) interface, a first number of memory dies and a second number of memory dies. Each memory die in a stack of memory dies is connected to the other memory die in the stack of memory dies in a cascading manner using interconnects or wire bonds. These connections establish electrical links from a substrate on which the memory stack is formed, a printed circuit board, or an interposer to the memory dies. As used herein, the term “printed circuity board” refers to a medium used to connect components to one another in a circuit. As used herein, the term “interposer” refers to a thin substrate that sits between two or more memory dies that allows them to communicate with each other. The lower memory die and the middle memory dies in the stack of memory dies share the same power and ground interconnects or wire bonds for each I/O interface. However, the topmost memory die in the stack of memory dies has separate power and ground interconnects or wire bonds for each I/O interface. This wire bonding or interconnect between the memory dies and the substrate or interposer helps reduce crosstalk by providing an alternate return current path for signals sent to the memory dies. This reduction in crosstalk helps mitigate crosstalk-induced jitter.

As the number of bits per memory device increases due to the increase in the number of memory dies in a memory device, the complexity of the electrical connections between the memory dies and the substrate, the printed circuit board, or the interposer increases. This results in electrical interconnects in close proximity interacting with each other and can contribute to an increased amount of crosstalk. As used herein, the term “crosstalk” refers to the interaction between the electromagnetic fields produced when electrical signals flow through the wires in a memory device. The interaction between the different electromagnetic fields can cause interference that degrades the magnitude of an electrical signal being transmitted to and/or from the memory device such that the signal may not be read accurately by the memory controller. This degradation of the signal can cause inaccurate reads within the memory device which can decrease the efficiency in which the memory device operates. For example, inaccurate reads can lead to errors in data processing and storage, which may necessitate additional error-checking and correction processes. These additional processes can reduce the overall speed and efficiency of the operation, as more effort is required to ensure data accuracy and integrity.

This interference can also lead to eye margin degradation. As used herein, the term “eye margin” refers to a vertical distance between amplitudes of two signals at a point in an eye diagram in which one signal reaches its highest amplitude in one (e.g., a positive direction) and the other signal reaches is highest amplitude in another (e.g., a negative direction), as well as the horizontal distance between the two points at which the two signals overlap before and after the point at which the highest amplitude was reached. As used herein, the term “eye diagram” refers to a diagram used to indicate the quality of a signal. Degradation of the eye margin is a decrease in the eye margin such that the aforementioned vertical and/or horizontal distance decreases due to jitter (e.g., interference) in the signal that decreases the quality of the signal.

In previous approaches, attempts had been made to improve eye margins for high speed data transfer to and from memory dies by reducing overall analog I/O block parasitic capacitance. As used herein, the term “parasitic capacitance” refers to an unwanted capacitance between multiple components in a memory device caused by the close proximity of the memory components. Pull-up drivers, pull-down drivers, electrostatic discharge (ESD) clamp diodes, and proprietary sub analog blocks contribute to the parasitic capacitance of the I/O lines.

To reduce I/O block parasitic capacitance, redesign and layout changes at the memory die level are necessary. The process of making the layout changes involves re-spinning the design and undergoing a complete cycle of testing and validation. The first step in the testing and validation process is design verification, which ensures that the new design meets all specified requirements and functions. This often involves simulation and formal verification techniques. Next is prototype fabrication, where a small batch of the redesigned memory dies is manufactured to create prototype memory dies. This allows for practical testing and evaluation. The next step in the process is functional testing, where the prototypes undergo rigorous testing to verify that they perform as expected under various conditions, including checks for correct operation, timing, and power consumption. After the functional testing, the memory dies undergo parametric testing, which involves measuring the electrical characteristics of the prototypes, such as voltage, current, and capacitance, to ensure they fall within acceptable ranges. Reliability testing is then performed. At this stage, the prototypes are subjected to stress tests to evaluate their durability and long-term reliability, including thermal cycling, voltage stress, and other environmental tests. Finally, the prototypes undergo validation, involving comprehensive testing of the prototypes in real-world scenarios to ensure they meet all performance and reliability standards. This may include system-level testing and integration with other components. Once the validation process is completed, further adjustments and optimizations may be made to the design based on the results. This iterative process continues until the design meets all requirements.

These previous approaches could result in an increase to the cost of manufacturing the memory dies due to having to undergo processes, including the process described above, to reduce the parasitic capacitance in a memory device. Further, undergoing the previously described process can increase the amount of time required to manufacture memory dies.

Embodiments of the present disclosure, however, can stack memory dies in a manner that improves the eye margin without reducing the I/O parasitic capacitance by bonding (e.g., coupling) memory dies in a manner that reduces crosstalk in a memory device. The crosstalk-induced jitter can be reduced by making an electrical connection to a stack of memory dies using different types of conductive lines (e.g., wires used to transmit a signal) in different configurations. For example, ground lines (e.g., conductive lines that connects one or more memory dies to ground) and power lines (e.g., conductive lines that connects one or more memory dies to a power source) can be connected to the stack of memory dies in a first configuration and data lines (e.g., conductive lines that transfer signals indicative of data between memory components) can be connected to the stack of memory dies in a second configuration that is different from the first configuration. Coupling different type of conductive lines to a stack of memory dies in different configurations can decrease crosstalk-induced jitter, as well as improve the eye margin of an eye diagram.

As used herein, “a,” “an,” or “a number of” can refer to one or more of something, and “a plurality of” can refer to two or more such things. For example, a memory device can refer to one or more memory devices, and a plurality of memory devices can refer to two or more memory devices.

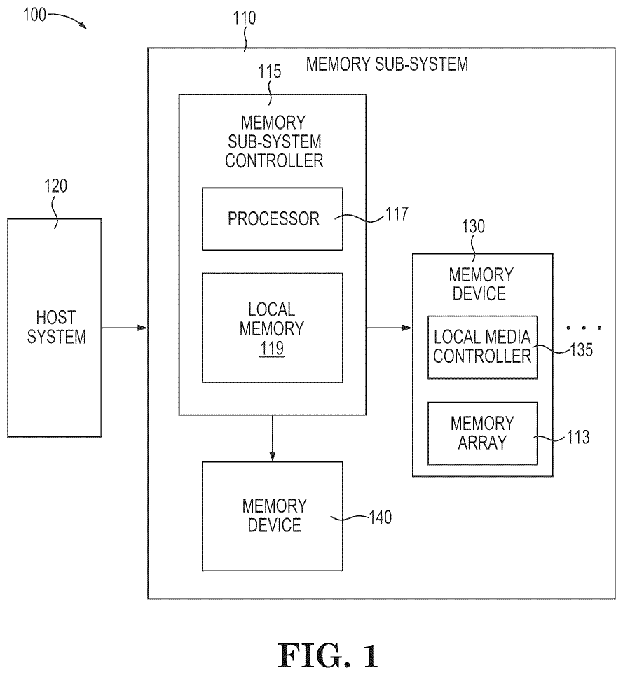

FIG. 1 illustrates an example computing system 100 that includes a memory sub-system 110 in accordance with some embodiments of the present disclosure. The memory sub-system 110 can include media, such as one or more non-volatile memory devices (e.g., memory device 140), one or more volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, discrete NAND, discrete LPDDR, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-systems 110. FIG. 1 illustrates one example of a host system 120 coupled to one memory sub-system 110. As used herein, the term “coupled to” or “coupled with” can refer to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via an interface (e.g., a physical host interface). Examples of an interface can include, but are not limited to, a serial advanced technology attachment (SATA) interface, a peripheral component interconnect express (PCIe) interface, universal serial bus (USB) interface, Fibre Channel, Small Computer System Interface (SCSI), Serial Attached SCSI (SAS), a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), Universal Serial Bus (USB), or any other interface. The interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the PCIe interface. The interface can provide a way for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 130) can be, but are not limited to, random access memory (RAM), such as dynamic random access memory (DRAM) and synchronous dynamic random access memory (SDRAM).

Some examples of non-volatile memory devices (e.g., memory device 140) include negative-and (NAND) type flash memory and write-in-place memory. NAND type flash memory includes, for example, two-dimensional NAND (2D NAND) and three-dimensional NAND (3D NAND).

Each of the memory devices 130 can include one or more arrays of memory cells (e.g., memory array 113). One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, an MLC portion, a TLC portion, a QLC portion, or a PLC portion of memory cells. The memory cells of the memory devices 130 can be grouped as pages that can refer to a logical unit of the memory device used to store data. With some types of memory (e.g., DRAM), pages can be grouped to form blocks.

Although non-volatile memory components such as NAND type memory (e.g., 2D NAND, 3D NAND) are described, the memory device 140 can be based on any other type of non-volatile memory or storage device, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can be a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface (not pictured) circuitry to communicate with the host system 120 via a physical host interface (not pictured).

The host interface circuitry can convert the commands received from the host system into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device 130 and/or the memory device 140.

In some embodiments, the memory device 130 includes local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

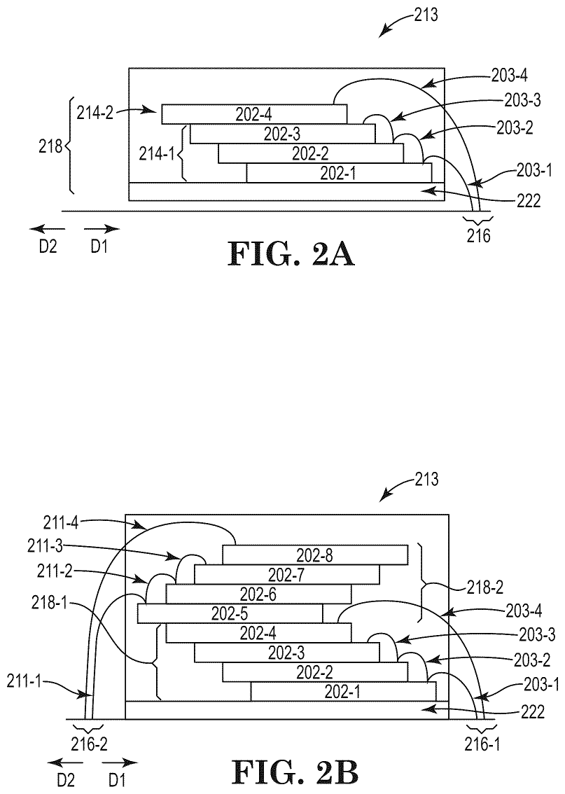

The memory array 113 can include a plurality of memory dies. In some embodiments, as will be described in more detail in FIGS. 2A-2B, the plurality of memory dies can be stacks of memory dies that are stacked in a cascading pattern. Each memory die in a respective stack of memory dies can be coupled to an interface and/or a different memory component via conductive lines. For example, conductive lines can couple a plurality of memory dies to ground, to a power source, to a controller, or other memory components. In some embodiments, the ground lines and the power lines can be coupled to the plurality of memory dies in a configuration that is independent of the configuration in which the signal lines are coupled to the same plurality of memory dies.

FIG. 2A illustrates a bonding scheme for reduced crosstalk-induced jitter in a memory device in accordance with some embodiments of the present disclosure. FIG. 2A includes a memory array 213 that includes memory dies 202-1, 202-2, 202-3, 202-4 (individually or collectively referred to as memory dies 202), a first conductive link 203-1, a second conductive link 203-2, a third conductive link 203-3, and a fourth conductive link 203-4 (individually or collectively referred to as conductive links 203). The memory array 213 can include a first number of memory dies 214-1. Each memory die 202 of the first number of memory dies 214-1 can be coupled to a different memory die 202 of the first number of memory dies 214-1 in a cascading pattern via one more first conductive links 203-1, one or more conductive links 203-2, and/or one or more third conductive links 203-3 forming a first portion of a conductive path to an input/output (I/O) interface 216.

The memory array 213 can also include a second number of memory dies 214-2 coupled to the I/O interface 216 via one or more fourth conductive links 203-4 forming a second portion of a conductive path to the I/O interface 216. The second number of memory dies 214-2 is stacked on the first number of memory dies 214-1 in the cascading pattern. In some embodiments, the first number of memory dies 214-1 can be three memory dies 202 and the second number of memory dies 214-2 can be one memory die 202. For example, the first number of memory dies 202 can include memory dies 202-1, 202-2, 202-3 and the second number of memory dies 202 can include memory die 202-4.

In some embodiments, the aforementioned cascading pattern in which the stack of memory dies 218 is stacked can be formed by stacking each of the first number of memory dies 214-1 on each other such that a first memory die 202-1 of the first number of memory dies 214-1 is formed on a substrate 222. Further, the cascading pattern can be formed such that a second memory die 202-2 of the first number of memory dies 214-1 can be formed on the first memory die 202-1 such that a first end of the first memory die 202-1 extends further than a first end of the second memory die 202-2 in a first horizontal direction D1 and a second end of the first memory die 202-1 extends less than a second end of the second memory die 202-2 in a second horizontal direction D2. Both the first horizontal direction D1 and the second horizontal direction D2 can be directions that are substantially parallel to the substrate 216. Further, the third memory die 202-3 of the first number of memory dies 214-1 can be formed on the second memory die 202-2 such that the first end of the second memory die 202-2 extends further than the first end of the third memory die 202-3 in the first horizontal direction D1 and a second end of the second memory die 202-2 extends less than a second end of the third memory die 202-3 in a second horizontal direction D2. Further, a fourth memory die 202-4 in the second number of memory dies 214-2 can be formed on the third memory die 202-3 such that a first end of the third memory die extends further than the first end of the fourth memory die 202-4 of the second number of memory dies 214-2 in the first horizontal direction D1 and the second end of the third memory die 202-3 extends less than the second end of the third memory die 202-3 in the second horizontal direction D2.

As shown in FIG. 2A, one or more first conductive links 203-1 can be coupled to a portion of the first memory die 202-1 that extends further than the second memory die 202-2 in the first horizontal direction D1 and the interface 216. One or more second conductive links 203-2 can be coupled to a portion of the first memory die 202-1 that extends further than the second memory die 202-2 in the first horizontal direction D1 and a portion of the second memory die 202-2 that extends further than the third memory die 202-3 in the first horizontal direction D1. Further, one or more third conductive links 203-3 can be coupled to the portion of the second memory die 202-2 that extends further than the third memory die 202-3 in the first horizontal direction D1 and a portion of the third memory die 202-3 that extends further than the fourth memory die 202-4 in the first horizontal direction D1. Further, one or more fourth conductive links 203-4 can be coupled to a portion of the fourth memory die 202-4 that extends less than the third memory die 202-3 in the first horizontal direction D1 and the interface 216.

In some embodiments, a first conductive link 203-1 can be a ground line link (e.g., VSS) that can couple the first number of memory dies 214-1 to ground via the interface 216. In these embodiments, the second conductive link 203-2, the third conductive link 203-3 and the fourth conductive link 203-4 can each be ground links that couple first memory die 202-1, the second memory die 202-2, the third memory die 202-3 and the fourth memory die 202-4 as previously described such that the first memory die 202-1, the second memory die 202-2, the third memory die 202-3 and the fourth memory die 202-4 to ground. In some embodiments, a first conductive link 203-1 can be a power line link (e.g., VDDQ) that can couple the first number of memory dies 214-1 to a power source via the interface 216. In these embodiments, the second conductive link 203-2, the third conductive link 203-3 and the fourth conductive link 203-4 can each be power line links that couple first memory die 202-1, the second memory die 202-2, the third memory die 202-3 and the fourth memory die 202-4 as previously described such that the first memory die 202-1, the second memory die 202-2, the third memory die 202-3 and the fourth memory die 202-4 to the power source.

FIG. 2B illustrates another embodiment of a bonding scheme for reduced crosstalk-induced jitter in a memory device in accordance with some embodiments of the present disclosure. FIG. 2B includes a memory array 213 that includes memory dies 202-1, 202-2, 202-3, 202-4, 202-5, 202-6, 202-7, 202-8. FIG. 2B also includes first conductive links 203-1 and 211-1, second conductive links 203-2 and 211-2, third conductive links 203-3 and 211-3, and fourth conductive links 203-4 and 211-4.

As stated in connection with FIG. 2A, the first conductive links 203-1 and 211-1, the second conductive links 203-2 and 211-2, the third conductive links 203-3 and 211-3 and the fourth conductive links 203-4 and 211-4 can be ground line links and/or power line links. FIG. 2B illustrates a first stack of memory dies 218-1 and a second stack of memory dies 218-2. In some embodiments, the second stack of memory dies 218-2 can be formed on the first stack of memory dies 218-1. Further, the first stack of memory dies 218-1 can be formed in a cascading pattern in a first direction D1 and the second stack of memory dies 218-2 can be formed in a cascading pattern in a second direction D1 that is different than the first direction D1.

In some embodiments, the conductive links 203 can be coupled to the first stack of memory dies 218-1 and the conductive links 211 can be coupled to the second stack of memory dies 218-2. As shown in FIG. 2B, the conductive links 203 can be coupled to the first side of the first stack of memory dies 218-1 and the second conductive links 211 can be coupled to a second side of the second stack of memory dies 218-2 that is on the opposite side of the first side of the first stack of memory dies 218-1. In some embodiments, the conductive links 203 can be a first plurality of ground line links or power line links and the second plurality of conductive links 211 can be a second plurality of ground line links or power line links 211. In some embodiments, the first stack of memory dies 218-1 and the second stack of memory dies 218-2 can each include four memory dies 202. Further, in some embodiments, the conductive links 203 can couple the first stack of memory dies 218-1 to a first I/O interface 216-1 and the conductive links 211 can couple the second stack of memory dies 218-2 to a second I/O interface 216-2. In some embodiments, the first I/O interface 216-1 can be a different I/O interface than the second I/O interface 216-2. In other embodiments, the first I/O interface 216-1 and the second I/O interface 216-2 can be the same I/O interface.

As illustrated in FIG. 2B, each conductive link 203-1, 203-2, 203-3, 203-4 is formed in extended portions of two respective memory dies (memory dies 202-1 and 202-2, memory dies 202-2 and 202-3, memory dies 202-3 and 202-4) or in an extended portion of the memory die 202-1 and the interface 216-1. This configuration, in which the conductive links 203 are coupled to the memory dies 202 and the interface 216 further allows the conductive links 203 (e.g., ground line links or power line links) to be formed in a cascading pattern along the memory dies 202 and the interface 216.

Coupling conductive links 203 to the first stack of memory dies 218-1 and coupling conductive links 211 to the second stack of memory dies 218-2 as shown in FIGS. 2A and 2B, can provide benefits over previous configurations. These benefits can include reducing crosstalk-induced jitter without implementing measures to reduce parasitic capacitance. As stated previously, the crosstalk-induced jitter can be reduced by coupling different types of conductive lines to a stack of memory dies in different configurations. For example, ground line links and power line links can be coupled to the stack of memory dies in a first configuration and data line links can be coupled to the stack of memory dies in a second configuration that is different from the first configuration. More particularly, while the two portions of a conductive path shown in FIG. 2A are independently formed (one portion of the conductive path formed using the conductive line 203-4 and another portion of the conductive path formed using the conductive lines 203-1, 203-2, and 203-3) respectively for power and/or ground line links, the data line link can be formed using conductive path that has a single portion, in which two conductive links are formed along two of the memory dies 202 in a cascading pattern. Coupling different type of conductive links to a stack of memory dies in different configurations can decrease crosstalk-induced jitter, as well as improve the eye margin of an eye diagram.

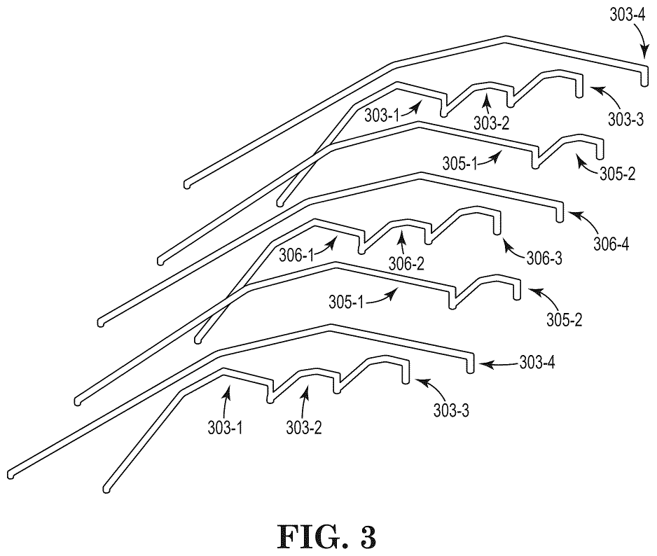

FIG. 3 illustrates conductive links for memory die coupling in a memory device in accordance with some embodiments of the present disclosure. The conductive links illustrated in FIG. 3 includes first ground line links 303-1, second ground line links 303-2, third ground line links 303-3, and fourth ground line links 303-4 (individually or collectively referred to as ground line links 303). The conductive links further include a first power line link 306-1, a second power line link 306-2, a third power line link 306-3 and a fourth power line link 306-4 (individually or collectively referred to as power line links 306). Further, the conductive links include first signal line links 305-1, and a second signal line links 305-2 (individually or collectively referred to as signal line links 305).

Thet ground line links 303, the power line links 306, and the signal line links 305 can all be coupled to the same stack of memory dies simultaneously. Further, the ground line links 303 and the power line links 306 can be coupled to the stack of memory dies in a first conductive path and the signal line links 305 can be coupled to the stack of memory dies in a second conductive path. As used herein, the term “conductive path” refers to the route through which conductive links transfer electrical signals to different memory components. For example, the first ground line links 303-1, and the first power line link 306-1 can couple a first memory die (e.g., first memory die 202-1 in the first stack of memory dies 218-1 or first memory die 202-5 in the second stack of memory dies 218-2 in FIG. 2B) to an interface (e.g., 216-1 or 216-2 in FIG. 2B), the second ground line links 303-2 and the second power line link 306-2 can couple the first memory die to a second memory die (e.g., memory die 202-2 in the first stack of memory dies 218-1 or memory die 202-6 in the second stack of memory dies 218-2 in FIG. 2B), the third ground line links 303-3 and the third power line link 306-3 can couple the second memory die to a third memory die (e.g., memory die 202-3 in the first stack of memory dies 218-1 or memory die 202-7 in the second stack of memory dies 218-2 in FIG. 2B), and the fourth ground line links 303-4 and the fourth power line link 306-4 can couple the third memory die to a fourth memory die (e.g., memory die 203-4 in the first stack of memory dies 218-1 or memory die 203-8 in the second stack of memory dies 218-2 in FIG. 2B). The first conductive path and the second conductive path can correspond to a first configuration of conductive links and a second configuration of conductive links, respectively. Therefore, the ground line links 303 and the power line link 306 can be coupled to the stack of memory dies in a configuration independent of a configuration in which the signal line links 305 are coupled to the stack of memory dies. In some embodiments, a first signal line link 305-1 and second signal line link can transfer a first type of signal and a different first line link 305-1 and a different second signal line link 305-2 can transfer a second type of signal. In some embodiments, the first type of signal can be a different type of signal than the second type of signal. For example, the first type of signal can be a signal indicative of instructions to perform a memory operation, a signal indicative of data being stored in or retrieved from a memory array, or another type of electrical signal. In some embodiments, the second type of signal can be a different one of the listed types of signals than the first type of signal. In other embodiments, the first type of signal and the second type of signal can be the same type of signal.

In some embodiments, the ground line links 303 can couple the stacks of memory dies to ground via the I/O interface, the power line links 306 can couple the stacks of memory dies to a power source via the I/O interface, and the signal line links 305 can couple the stacks of memory dies to another memory component via the I/O interface. In some embodiments, the other memory component can be a host (e.g., host 120 in FIG. 1), a controller (e.g., memory sub-system controller 115 in FIG. 1), or another memory device (e.g., memory device 140 in FIG. 1, or any other memory component). In some embodiments, a plurality of signal line links 305 can couple the stacks of memory dies to a first memory component and a different plurality of signal line links 305 can couple the stacks of memory dies to a second memory component that is different than the first memory component. In other embodiments, the first memory component and the second memory component can be the same memory component.

As stated previously, coupling the conductive line links to the stacks of memory dies, as described herein, can reduce crosstalk-induced jitter in a memory device. This reduction in crosstalk-induced jitter can be caused by the ground line links 303 and the power line links 306 forming conductive paths that have a different shape than the shape of the conductive path formed by the signal line links 305. This difference in the shapes of the conductive paths can reduce crosstalk-induced jitter because there is more distance between portions of the conductive path formed by each of the signal line links 305 and the conductive path formed by the ground line links 303 and 304, as well as the conductive path formed by the power line links 306 compared to previous approaches in which the conductive paths of the ground line links 303, power line links 306, and the signal line links 305 have the same shape.

In some embodiments, this decrease in crosstalk-induced jitter allows for a greater memory density and a higher data transfer speed than previous approaches. For example, previous approaches to memory die coupling in a memory device could support data transfer speeds of 6400 megabits per second (Mbps). However, embodiments of the memory die coupling to a memory device as described herein can support data transfer speeds up to 9600 Mbps or higher.

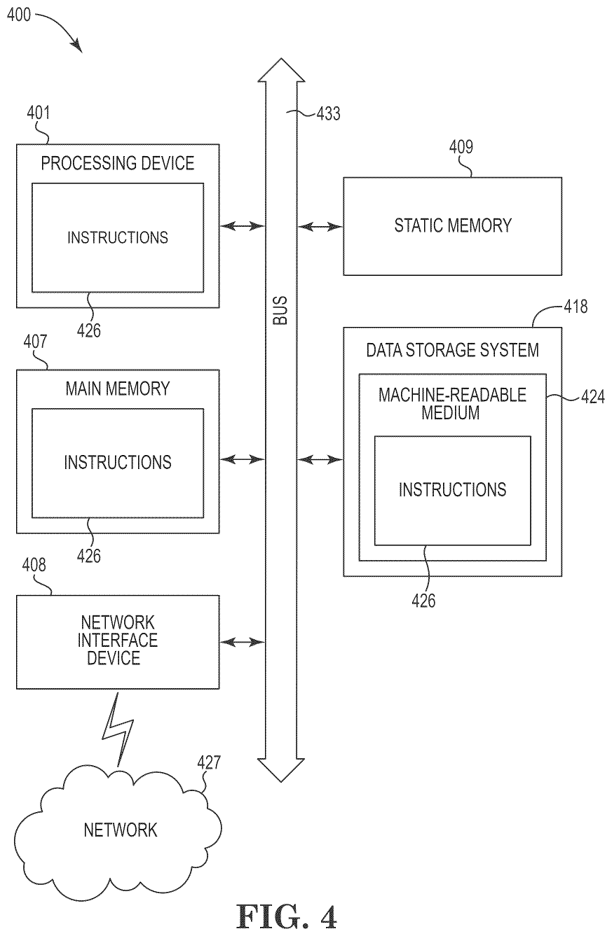

FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 in FIG. 1) that includes, is coupled to, or utilizes a memory sub-system (e.g., the memory sub-system 110 in FIG. 1) or can be used to perform the operations of a controller on data in a memory array (e.g., memory array 113 in FIG. 1) that includes conductive line links coupled to stacks of memory dies in multiple configurations as previously described. In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 401, a main memory 407 (e.g., read-only memory (ROM), flash memory, dynamic random access memory (DRAM) such as synchronous DRAM (SDRAM) or Rambus DRAM (RDRAM), etc.), a static memory 409 (e.g., flash memory, static random access memory (SRAM), etc.), and a data storage system 418, which communicate with each other via a bus 433.

The processing device 401 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 401 can also be one or more special-purpose processing devices such as an application specific integrated circuit (ASIC), a field programmable gate array (FPGA), a digital signal processor (DSP), network processor, or the like. The processing device 401 is configured to execute instructions 426 for performing the operations and steps discussed herein. The computer system 400 can further include a network interface device 408 to communicate over the network 427.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 407 and/or within the processing device 401 during execution thereof by the computer system 400, the main memory 407 and the processing device 401 also constituting machine-readable storage media. The machine-readable storage medium 424, data storage system 418, and/or main memory 407 can correspond to the memory sub-system 110 in FIG. 1.

In one embodiment, the instructions 426 include instructions to implement functionality corresponding to transferring electrical signals through the conductive line links coupled in different configurations to stacks of memory dies in a memory array (e.g., memory array 113 in FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Although specific embodiments have been illustrated and described herein, those of ordinary skill in the art will appreciate that an arrangement calculated to achieve the same results can be substituted for the specific embodiments shown. This disclosure is intended to cover adaptations or variations of a number of embodiments of the present disclosure. It is to be understood that the above description has been made in an illustrative fashion, and not a restrictive one. Combination of the above embodiments, and other embodiments not specifically described herein will be apparent to those of ordinary skill in the art upon reviewing the above description. The scope of a number of embodiments of the present disclosure includes other applications in which the above structures and methods are used. Therefore, the scope of a number of embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
an input/output (I/O) interface;
a first number of memory dies, wherein each memory die of the first number of memory dies is coupled to a different memory die of the first number of memory dies in a cascading pattern via one or more first conductive line links forming a first portion of a ground path to the I/O interface; and
a second number of memory dies coupled to the I/O interface via one or more second conductive line links forming a second portion of the ground path to the I/O interface, wherein the second number of memory dies is stacked on the first number of memory dies in the cascading pattern.

2. The apparatus of claim 1, wherein the first number of memory dies includes three memory dies.

3. The apparatus of claim 1, wherein the second number of memory dies includes one memory die.

4. The apparatus of claim 1, wherein the cascading pattern is formed by stacking each of the first number of memory dies on each other such that:
a first memory die of the first number of memory dies is formed on a substrate;
a second memory die of the first number of memory dies is formed on the first memory dies such that a first end of the first memory die extends further than a first end of the second memory die in a first horizontal direction and a second end of the first memory die extends less than a second end of the second memory die in a second horizontal direction;
a third memory die of the first number of memory dies is formed on the second memory dies such that the first end of the second memory die extends further than the first end of the third memory die in the first horizontal direction and a second end of the second memory die extends less than a second end of the third memory die in a second horizontal direction; and
a memory die in the second number of memory dies is formed on the third memory dies such that a first end of the third memory die extends further than the first end of the memory die of the second number of memory dies in the first horizontal direction and the second end of the third memory die extends less than the second end of the third memory die in a second horizontal direction.

5. The apparatus of claim 4, wherein the one or more first conductive lines is coupled to:
a portion of the first memory die in the first number of memory dies that extends further than the second memory die in the first number of memory dies in the first horizontal direction;
a portion of the second memory die in the first number of memory dies that extends further than the third memory die in the first number of memory dies in the first horizontal direction; and
a portion of the third memory die in the first number of memory dies that extends further than the second memory die in the first number of memory dies in the first horizontal direction.

6. The apparatus of claim 4, wherein the one or more second conductive lines is coupled to a portion the memory die in the second number of memory dies that extends less than the third memory die in the first number of memory dies in the first horizontal direction.

7. The apparatus of claim 1, further comprising first power line links to couple the first number of memory dies to a power source.

8. The apparatus of claim 5, further comprising second power line links to couple the second number of memory dies to a power source.

9. An apparatus, comprising:
a substrate;
a memory device formed on the substrate, wherein the memory device comprises:
a first memory die;
a second memory die on the first memory die;
a third memory die on the second memory die; and
a fourth memory die on the third memory die;
a plurality of first ground line links coupled to an input/output (I/O) interface, the first memory die, the second memory die, and the third memory die;
a plurality of second ground line links coupled to the I/O interface and the fourth memory device;
a plurality of first power line links coupled to the I/O interface, the first memory die, the second memory die, and the third memory die;
a second plurality of power line links coupled to the I/O interface and the fourth memory die;
first signal line links coupled to the substrate, the third memory die, and the fourth memory die; and
second signal line links coupled to the substrate, the third memory die, and the fourth memory die.

10. The apparatus of claim 9, wherein the memory device is a dynamic random access memory (DRAM) memory device.

11. The apparatus of claim 9, wherein the plurality of first ground line links, the plurality of second ground line links, the plurality of first power line links, and the plurality second power line links are coupled to the memory device in a first conductive path, and the first signal line links and the second signal line links are coupled to the memory device in a second conductive path that is different than the first conductive path.

12. The apparatus of claim 9, wherein the first signal line links transfers a first type of signal and the second signal line links transfers a second type of signal that is different than the first type of signal.

13. A system, comprising:
a host;
a memory device coupled to the host, wherein the memory device includes:
a plurality of stacks of memory die;
a first plurality ground line links to couple a first memory die, a second memory die, and a third memory die in a respective stack of memory die to ground;
a second plurality of ground line links to couple a fourth memory die in the respective stack of memory die to ground;
a first plurality of power line links to couple the first memory die, the second memory die, and the third memory die of the respective stack to a power source;
a second plurality power line links to couple the fourth memory die of the respective stack of memory die to the power source;
a first plurality signal line links to couple the third memory die and the fourth memory die of the respective stack of memory die to a first memory component; and
a second plurality signal line links to couple the third and fourth memory die of the respective stack of memory die to a second memory component.

14. The system of claim 13, wherein the plurality of stacks of memory die include a first stack of memory die and a second stack of memory die.

15. The system of claim 14, wherein the second stack of memory die is on the first stack of memory die.

16. The system of claim 14, wherein the first stack of memory die is arranged in a cascading pattern in a first direction.

17. The system of claim 16, wherein the second stack of memory die is arranged in a cascading pattern in a second direction that is different than the first direction.

18. The system of claim 14, wherein the first and second pluralities of ground line links, the first and second pluralities of power lines, and the first and second pluralities of signal line links are coupled to the first stack of memory die and different pluralities of ground line links, different pluralities of power lines, and different pluralities of signal lines are coupled to the second stack of memory die.

19. The system of claim 18, wherein the first and second pluralities of ground line links, the first and second pluralities of power line links, and the first and second pluralities of signal line links are coupled to the first stack of memory die on a first side of the memory device and the different pluralities of ground line links, the different pluralities of power line links, and the different pluralities of signal line links are coupled to the second stack of memory die on a second side of the memory device that is on an opposite side of the memory device than the first side of the memory device.

20. The system of claim 14, wherein each of the plurality of stacks of memory dies includes four memory dies.
